(19) United States
(12) Patent Application Publication
(10) Pub. No.: US 2026/0068517 A1
(43) Pub. Date: Mar. 5, 2026

(54) GROUP III-V COLLOIDAL QUANTUM DOTS COMPRISING DIFFERENT LIGANDS, METHOD FOR PREPARING ECO-FRIENDLY SOLVENT-BASED INK BY USING SAME, AND OPTOELECTRONIC DEVICE USING SAME

(71) Applicant: Korea University Research and Business Foundation, Seoul (KR)

(72) Inventors: Se-Woong BAEK, Seoul (KR); Min-Jae SI, Seoul (KR)

(21) Appl. No.: 19/105,434

(22) PCT Filed: Aug. 18, 2023
(86) PCT No.: PCT/KR2023/012300

§ 371 Date: Feb. 21, 2025

(30) Foreign Application Priority Data
Aug. 22, 2022 (KR) 10-2022-0105083
Apr. 6, 2023 (KR) 10-2023-0045473

(51) Int. Cl. H10K 85/30; B82Y 15/00; B82Y 20/00; B82Y 40/00; C09D 11/033; C09D 11/037

(52) U.S. Cl. CPC H10K 85/321; C09D 11/033; C09D 11/037; B82Y 15/00; B82Y 20/00; B82Y 40/00

(57) ABSTRACT

The present invention relates to a ligand exchange technique for III-V group colloidal quantum dots. By employing a ligand surface treatment method, the invention facilitates the ligand exchange process in III-V group quantum dots while enhancing their solvent dispersibility. Furthermore, by substituting heterogeneous ligands, the invention enables the production of quantum dot ink based on environmentally friendly solvents and its application in device fabrication. Accordingly, the present invention proposes III-V group colloidal quantum dots incorporating heterogeneous ligands, a method for manufacturing environmentally friendly solvent-based quantum dot ink, and an optoelectronic device utilizing the ink.

### CROSS-REFERENCE TO RELATED APPLICATIONS

This application claims priority to and the benefit of Korean Patent Application No. 10-2022-0105083 and Korean Patent Application No. 10-2023-0045473 filed in the Korean Intellectual Property Office on Aug. 22, 2022 and Apr. 6, 2023, the entire contents of which are incorporated herein by reference.

### TECHNICAL FIELD

The present invention relates to a ligand exchange technique for III-V group colloidal quantum dots. More specifically, the invention pertains to colloidal quantum dots in which heterogeneous ligands are substituted on the surface of the quantum dots, a method for producing quantum dot ink based on an environmentally friendly solvent using the substituted colloidal quantum dots, and a method for fabricating an optical sensor device utilizing the quantum dot ink.

### BACKGROUND ART

With the advancement of robotics and the computer industry, extensive research has been conducted on electronic materials with absorption bands in the non-visible spectrum, particularly in the infrared (IR) region, for recognition purposes. These materials have found applications in various fields such as autonomous driving, temperature sensing, medical diagnostics, telecommunications, and security, leading to an increasing demand. Among them, materials that can be processed using low-temperature solution-based methods offer advantages over traditional vacuum deposition materials due to their relatively lower cost and ease of mass production.

Colloidal quantum dot (CQD) materials capable of infrared absorption and emission can be dispersed in solvents and deposited as thin films using methods such as spin-coating and blade-coating. These CQDs are typically synthesized with oleic acid ligands attached to their surfaces to ensure stable dispersion in ink form. However, for device fabrication, the long ligands need to be replaced with shorter ligands to enhance electrical properties.

Most infrared CQDs are composed of highly toxic heavy metals such as Pb, Cd, and Hg. In contrast, III-V group CQDs, such as indium arsenide (InAs) and indium antimonide (InSb), exhibit lower toxicity. However, unlike II-VI and IV-VI group CQDs, III-V group CQDs possess covalent lattice structures with charge imbalances, making passivation challenging to prevent impurity incorporation. As a result, there is a need for an improved ligand exchange method.

Additionally, as shorter ligands bind to the CQD surface, the increased intermolecular interactions among ligands result in solubility only in highly polar solvents. This limitation necessitates the use of toxic organic solvents such as N,N-dimethylformamide (DMF) in device fabrication processes.

Furthermore, surface treatment of III-V group CQDs differs from that of II-VI and IV-VI group CQDs due to their covalent lattice structures, which have high bonding energies. The presence of long organic ligands on the CQD surface during synthesis causes steric hindrance, making ligand exchange in solution difficult. Moreover, when organic ligands with fewer than three carbon chains are used, as reported in conventional methods, ligand aggregation occurs, preventing the ink from maintaining stability in non-polar solvents.

Therefore, there is a growing need for a surface treatment method that ensures both electrical performance and dispersion in environmentally friendly solvents for III-V group CQDs, along with a device fabrication technique utilizing such an ink.

### SUMMARY OF THE INVENTION

The present invention has been devised in consideration of the aforementioned issues and aims to facilitate ligand exchange in III-V group quantum dots by employing a ligand surface treatment method, thereby enhancing solvent dispersibility. More specifically, the invention provides III-V group colloidal quantum dots incorporating heterogeneous ligands, enabling the fabrication of quantum dot ink based on environmentally friendly solvents and its application in device fabrication.

Another objective of the present invention is to provide a method for manufacturing quantum dot ink using heterogeneous ligand-exchanged III-V group colloidal quantum dots and to offer optoelectronic devices utilizing the ink.

Additional objects and advantages of the present invention will be described below and will become apparent through the embodiments of the invention. Furthermore, the objectives and advantages of the present invention can be realized through the means and combinations set forth in the claims.

To achieve the aforementioned objectives, the III-V group quantum dot incorporating heterogeneous ligands comprises: a quantum dot core, which forms the main body of the quantum dot and is composed of III-V group elements; an aromatic ligand portion, which is substituted on the surface of the quantum dot core; and a thiol ligand portion, which is also substituted on the surface of the quantum dot core along with the aromatic ligand portion.

The quantum dot core may be composed of a chalcogenide-based quantum dot or a binary compound.

Specifically, the quantum dot core may be a first compound comprising indium (In) and at least one element selected from phosphorus (P), arsenic (As), and antimony (Sb), or a second compound comprising lead (Pb) and at least one element selected from sulfur (S) and selenium (Se), wherein the quantum dot core is selected from the group consisting of the first compound and the second compound.

Furthermore, the method for preparing an environmentally friendly solvent-based ink using III-V group colloidal quantum dots incorporating heterogeneous ligands comprises the steps of: (A) Preparing a quantum dot solution; (B) Preparing a precursor solution by dispersing aromatic ligands and thiol ligands in a solvent; (C) Stirring and mixing the precursor solution of step (B) with the quantum dot solution of step (A) to induce a reaction; (D) Adding hexane to the reaction mixture of step (C), followed by centrifugation to precipitate the quantum dots and remove unreacted ligands; (E) Redispersing the processed product from step (D) in a low-polarity or environmentally friendly solvent; (F) Drying the product obtained in step (E) to remove residual solvent; and (G) Dispersing the dried product from step (F) in a low-polarity or environmentally friendly solvent.

Step (D) and step (E) may be sequentially repeated two to three times.

In step (A), the quantum dot solution is prepared as a ligand-exchanged quantum dot solution dissolved in a solvent. The quantum dot may be a first compound comprising indium (In) and at least one element selected from phosphorus (P), arsenic (As), and antimony (Sb), or a second compound comprising lead (Pb) and at least one element selected from sulfur (S) and selenium (Se), wherein the quantum dot is selected from the group consisting of the first compound and the second compound. The solvent may be n-octane, and the ligand may be selected from the group consisting of oleic acid, myristic acid, lauric acid, palmitic acid, stearic acid, oleylamine, n-octylamine, hexadecylamine, hexyl phosphonic acid, n-octyl phosphonic acid, tetradecyl phosphonic acid, and octadecyl phosphonic acid, or a combination of two or more thereof.

Furthermore, the optoelectronic device achieving the objectives of the present invention comprises a photosensing-based optoelectronic device including a quantum dot light absorption layer, wherein the quantum dot light absorption layer is formed by thin-film coating with quantum dot ink, which is prepared by dispersing III-V group colloidal quantum dots incorporating heterogeneous ligands in a low-polarity or environmentally friendly solvent. The heterogeneous ligands of the III-V group colloidal quantum dots include aromatic ligands and thiol ligands.

The quantum dot light absorption layer may have a thickness in the range of 100 nm to 1000 nm.

The III-V group colloidal quantum dots may be composed of chalcogenide-based quantum dots or binary compounds.

Various embodiments for achieving the above objectives will be described in more detail below, and the following specific and detailed descriptions will further expand the understanding of the present invention.

According to the present invention, the ligand surface treatment method facilitates the ligand exchange process in III-V group quantum dots. Additionally, by employing an environmentally friendly solvent, the dispersibility of the quantum dots during ligand exchange can be enhanced. As a result, the present invention enables the fabrication of colloidal quantum dots with heterogeneous ligand substitution using aromatic ligands and thiol ligands, as well as the production of environmentally friendly solvent-based quantum dot ink and optoelectronic devices, thereby achieving superior electrical properties.

Furthermore, the present invention provides excellent solvent dispersibility, allowing dispersion in low-polarity solvents and, in particular, environmentally friendly solvents. This enables the production of highly stable quantum dot ink, ensuring process flexibility and facilitating thin-film deposition through solution processing.

Moreover, through the surface treatment method involving heterogeneous ligand substitution, the present invention enables the fabrication of highly responsive sensor-based optoelectronic devices, thereby achieving significant advantages in optical sensing applications.

### BRIEF DESCRIPTION OF THE DRAWINGS

FIG. 1 is a structural diagram illustrating a III-V group colloidal quantum dot incorporating heterogeneous ligands according to an embodiment of the present invention.

FIG. 2 is a photograph showing the quantum dot ink produced by the environmentally friendly solvent-based ink manufacturing method using III-V group colloidal quantum dots incorporating heterogeneous ligands, according to an embodiment of the present invention.

FIG. 3 is a structural diagram illustrating an optoelectronic sensor unit fabricated using III-V group colloidal quantum dots incorporating heterogeneous ligands, according to an embodiment of the present invention.

FIG. 4 is a characteristic graph showing the absorbance of the III-V group colloidal quantum dot ink incorporating heterogeneous ligands, as measured using an ultraviolet-visible (UV-Vis) spectrophotometer, according to an embodiment of the present invention.

FIG. 5 is a characteristic graph illustrating the photoresponse characteristics of the optoelectronic sensor unit fabricated using III-V group colloidal quantum dots incorporating heterogeneous ligands, according to an embodiment of the present invention.

### DETAILED DESCRIPTION

An exemplary embodiment of the present invention will be described with reference to the accompanying drawings, and an object and the configuration, and the features of the present invention will be understood well through the detailed description.

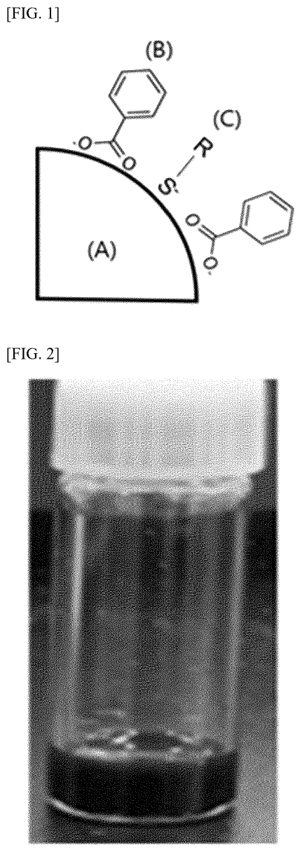

### FIG. 1: Structure of III-V Group Colloidal Quantum Dot Incorporating Heterogeneous Ligands

FIG. 1 illustrates the structure of a III-V group colloidal quantum dot incorporating heterogeneous ligands according to an embodiment of the present invention.

Referring to FIG. 1, the III-V group colloidal quantum dot of the present invention comprises: a quantum dot core (A), an aromatic ligand portion (B) and a thiol ligand portion (C).

The quantum dot core (A) forms the main body of the quantum dot and is composed of III-V group elements.

The core (A) may be a chalcogenide-based quantum dot or a binary compound.

More specifically, the quantum dot core (A) may be a first compound comprising indium (In) and at least one element selected from phosphorus (P), arsenic (As), and antimony (Sb), or a second compound comprising lead (Pb) and at least one element selected from sulfur (S) and selenium (Se), wherein the quantum dot core is selected from the group consisting of the first compound and the second compound.

The first compound may have a composition ratio of In:(P, As, Sb)=1.5-2.5:0.8-1.5 (by weight or molar ratio).

The second compound may have a composition ratio of Pb:(S, Se)=1-2:0.5-1.5 (by weight or molar ratio).

The quantum dot core (A) may have a size in the nanometer scale.

The aromatic ligand portion (B) is substituted on the surface of the quantum dot core (A) and plays a role in assisting ligand exchange reactions with thiol ligands while also enhancing dispersibility by charge stabilization.

The thiol ligand portion (C) is also substituted on the surface of the quantum dot core (A) along with the aromatic ligand portion (B) and serves a crucial function in determining the electrical properties of the quantum dot.

The thiol ligand portion (C) includes alkyl groups ranging from C1 to C3.

The thiol ligand portion (C) reduces ligand-ligand interactions in the benzene ring of the aromatic ligand portion (B) and enhances interactions with the solvent when mixed in ink formulations, thereby minimizing quantum dot aggregation and enabling the formation of a highly uniform thin film during solution processing.

Moreover, by incorporating the thiol ligand portion (C) together with the aromatic ligand portion (B), the long organic ligands (e.g., oleic acid) initially attached to the quantum dot can be effectively removed, making the surface more accessible for thiol ligand exchange.

By controlling the concentration of thiol and aromatic ligands, the electrical properties of the quantum dots can be tuned. The III-V group colloidal quantum dots of the present invention exhibit light absorption and emission in the near-infrared (NIR) range of 900-1600 nm.

Furthermore, the III-V group colloidal quantum dots incorporating heterogeneous ligands can be dispersed in low-polarity or environmentally friendly solvents such as chlorobenzene, 1,2-dichlorobenzene, tetrahydrofuran (THF), 2-methylanisole, and 2-methyltetrahydrofuran, either individually or in combinations of two or more. When dispersed in such solvents, the quantum dot ink can be used for thin-film coating while maintaining a high-quality, aggregation-free state.

The environmentally friendly solvent-based quantum dot ink manufacturing method using III-V group colloidal quantum dots incorporating heterogeneous ligands includes the following steps:
(A) The quantum dot solution is prepared by dissolving ligand-exchanged quantum dots in a solvent. The quantum dots may be either:
   A first compound containing indium (In) and at least one of phosphorus (P), arsenic (As), or antimony (Sb), or
   A second compound containing lead (Pb) and at least one of sulfur (S) or selenium (Se).

The solvent may be selected from n-octane, n-hexane, or toluene, either individually or in combinations.

The ligand initially bound to the quantum dots may be selected from oleic acid, myristic acid, lauric acid, palmitic acid, stearic acid, oleylamine, n-octylamine, hexadecylamine, hexyl phosphonic acid, n-octyl phosphonic acid, tetradecyl phosphonic acid, and octadecyl phosphonic acid, either individually or in combinations.
(B) Aromatic and thiol ligands are dispersed in a solvent. To facilitate dispersion, the solvent may be selected from chlorobenzene, 1,2-dichlorobenzene, tetrahydrofuran (THF), 2-methylanisole, 2-methyltetrahydrofuran, or toluene, either individually or in combinations.
(C) The precursor solution from step (B) is stirred and mixed with the quantum dot solution from step (A) to initiate a ligand exchange reaction under a nitrogen atmosphere.
(D) Hexane is added to the reaction mixture from step (C), followed by centrifugation to precipitate the quantum dots and remove unreacted ligands.
(E) The processed quantum dots are redispersed in a low-polarity or environmentally friendly solvent at an absolute temperature range of 290-340K to maintain solubility and prevent quantum dot degradation. The solvent may be selected from chlorobenzene, 1,2-dichlorobenzene, tetrahydrofuran (THF), 2-methylanisole, or 2-methyltetrahydrofuran, either individually or in combinations. Steps (D) and (E) may be sequentially repeated 2 to 3 times.
(F) The redispersed quantum dot solution from step (E) is dried to remove residual solvents.
(G) The dried quantum dots from step (F) are dispersed in a low-polarity or environmentally friendly solvent at the desired concentration.

The resulting ink maintains a high-quality, aggregation-free state, as shown in FIG. 2.

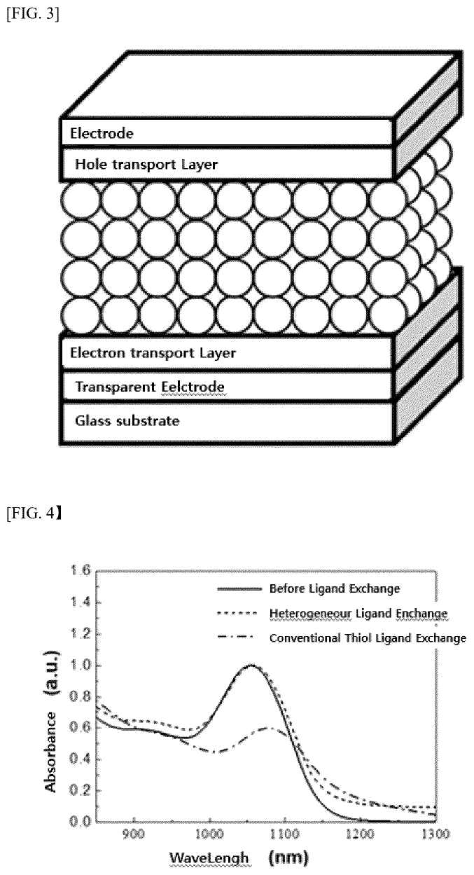

Meanwhile, referring to FIG. 3, the optoelectronic device utilizing the III-V group colloidal quantum dots incorporating heterogeneous ligands and the environmentally friendly solvent-based ink manufacturing method is described as follows.

As shown in FIG. 3, the optoelectronic device of the present invention is based on optical sensing and comprises: a substrate, a transparent electrode layer, an electron transport layer, a quantum dot light absorption layer, a hole transport layer, and an electrode layer.

The substrate may be either a rigid or flexible substrate.

The transparent electrode layer is formed on the upper surface of the substrate and may be composed of indium-tin oxide (ITO) or fluorine-doped tin oxide (FTO). The thickness of the transparent electrode layer may range from 10 nm to 100 nm.

The electron transport layer is formed on the upper surface of the transparent electrode layer and may be composed of a metal oxide paste selected from titanium dioxide (TiO₂), tin oxide (SnO₂), or zinc oxide (ZnO). The electron transport layer is formed by thin-film coating of the selected metal oxide paste, followed by heat treatment, and may have a thickness ranging from 10 nm to 200 nm.

The quantum dot light absorption layer is formed between the electron transport layer and the hole transport layer and serves as the most critical element for optical sensing. This layer is fabricated using quantum dot ink, which is prepared by dispersing III-V group colloidal quantum dots incorporating heterogeneous ligands in a low-polarity or environmentally friendly solvent. The layer can be deposited using spin-coating or other thin-film coating techniques.

The heterogeneous ligands of the III-V group colloidal quantum dots include aromatic ligands and thiol ligands, which are substituted on the surface of the quantum dot core.

The quantum dot light absorption layer may have a thickness ranging from 100 nm to 1000 nm. A thickness below 100 nm may result in reduced light absorption efficiency, while a thickness exceeding 1000 nm may lead to challenges in forming a uniform thin film due to the limitations of coating techniques.

The quantum dots and the ink used for thin-film coating in the quantum dot light absorption layer shall be as described in the aforementioned technical details.

The hole transport layer is formed on the upper surface of the quantum dot light absorption layer and may be composed of a metal oxide selected from nickel oxide (NiO), copper oxide (CuOx), or molybdenum oxide (MoOx). This layer may be deposited using thermal evaporation or thin-film coating techniques, with a thickness ranging from 5 nm to 50 nm.

The electrode layer is formed on the upper surface of the hole transport layer and may be composed of gold (Au), silver (Ag), or platinum (Pt).

The following section describes specific embodiments of the present invention, along with the testing of characteristics and the corresponding results.

### Example 1: Preparation of Quantum Dot Ink With Heterogeneous Ligand Substitution

A quantum dot solution (1 mL) containing oleic acid ligand-exchanged quantum dots dissolved in n-octane at a concentration of 20 mg/mL was mixed with 1 mL of a precursor solution, in which aromatic ligands and thiol ligands were dispersed in 2-methylanisole solvent. The mixture was then reacted under a nitrogen atmosphere with continuous shaking.

To remove unreacted ligands and quantum dots, 8 mL of hexane was added to the reaction mixture, followed by centrifugation to precipitate the quantum dots. The precipitated quantum dots were redispersed in a low-polarity solvent, and this process was repeated three times. The resulting quantum dots were then dried to remove residual solvents and finally dispersed in 2-methylanisole at the desired concentration, thereby producing the III-V group colloidal quantum dot ink incorporating heterogeneous ligands.

The absorption spectra of the quantum dot ink prepared in Example 1 were measured using UV-visible spectroscopy, and the results are shown in FIG. 4.

For comparison, the absorption spectra were also measured for quantum dots before heterogeneous ligand substitution and Quantum dots substituted with only thiol ligands

Here, the quantum dots before heterogeneous ligand substitution refer to oleic acid ligand-exchanged quantum dots dissolved in n-octane.

Upon analyzing the absorbance measurement graph in FIG. 4, the UV-visible spectroscopy (UV-vis) results indicate that the absorption peak remains sharp and well-defined after the heterogeneous ligand substitution reaction. This observation suggests that the aromatic ligand portion facilitates the ligand exchange reaction with thiol ligands and enhances dispersibility via charge stabilization. Consequently, the quantum dot ink with heterogeneous ligand substitution exhibits excellent dispersion stability.

Thus, compared to quantum dots before heterogeneous ligand substitution and quantum dots substituted with only thiol ligands, the quantum dot ink prepared in this invention demonstrates superior control over aggregation within the ink formulation.

### Example 2: Fabrication of an Optoelectronic Device Using Quantum Dots With Heterogeneous Ligand Substitution

A conductive glass substrate was first subjected to surface treatment using ultraviolet (UV) light and ozone. Then, a ZnO sol-gel solution was dispersed in 2-methoxyethanol and deposited as a thin film using spin-coating. The film was subsequently subjected to thermal treatment. On the ZnO-coated substrate, quantum dots with heterogeneous ligand substitution were dispersed in 2-methyltetrahydrofuran (MeTHF) at a concentration of 300 mg/mL and deposited using spin-coating under a nitrogen atmosphere to form a quantum dot thin film.

A hole transport layer and an electrode layer were sequentially formed using a thermal evaporator, depositing molybdenum oxide (MoOx) followed by gold (Au). The final optoelectronic device was fabricated with an active area of 0.1 cm².

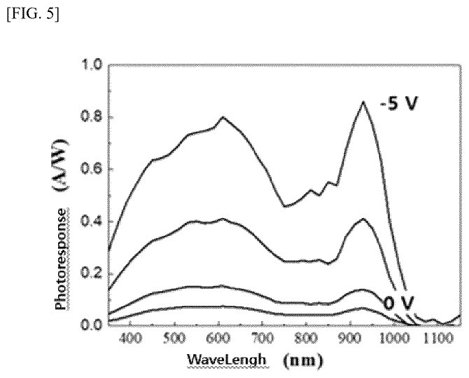

The photoresponse of the optoelectronic device fabricated in Example 2 was measured, and the results are presented in FIG. 5.

Upon analyzing the photoresponse measurement graph in FIG. 5, the optoelectronic device fabricated in Example 2 demonstrates high-efficiency light absorption and extraction, confirming its performance as a highly responsive optical sensor.

The present invention relates to a ligand exchange technique for III-V group colloidal quantum dots. By employing a ligand surface treatment method, the invention facilitates the ligand exchange process in III-V group quantum dots while enhancing their solvent dispersibility. Furthermore, by substituting heterogeneous ligands, the invention enables the production of quantum dot ink based on environmentally friendly solvents, which can be utilized in device fabrication. This technology has significant industrial applicability in various fields.

The exemplary embodiment described above is only to describe exemplary embodiment of the present invention and is not limited to the exemplary embodiment, and various modifications and variations are possible by those skilled in the art within the spirit and claims of the present invention, and it will be said that the modifications and variations fall within the scope of the technical rights of the present invention.

What is claimed is:

1. A III-V group colloidal quantum dot incorporating heterogeneous ligands, comprising:
A quantum dot core, which forms the quantum dot body and is composed of III-V group atoms;
An aromatic ligand portion, substituted on the surface of the quantum dot core; and
A thiol ligand portion, substituted on the surface of the quantum dot core along with the aromatic ligand portion.

2. The III-V group colloidal quantum dot incorporating heterogeneous ligands according to claim 1, wherein the quantum dot core is composed of a chalcogenide-based quantum dot or a binary compound.

3. The III-V group colloidal quantum dot incorporating heterogeneous ligands according to claim 1, wherein the quantum dot core comprises:
A first compound comprising indium (In) and at least one element selected from phosphorus (P), arsenic (As), and antimony (Sb); or
A second compound comprising lead (Pb) and at least one element selected from sulfur (S) and selenium (Se),
wherein the quantum dot core is selected from the group consisting of the first compound and the second compound.

4. The III-V group colloidal quantum dot incorporating heterogeneous ligands according to claim 1, wherein the quantum dot can absorb or emit light in the near-infrared (NIR) wavelength range of 900-1600 nm.

5. The III-V group colloidal quantum dot incorporating heterogeneous ligands according to claim 1, wherein the quantum dot is dispersed in a solvent selected from the group consisting of chlorobenzene, 1,2-dichlorobenzene, tetrahydrofuran (THF), 2-methylanisole, and 2-methyltetrahydrofuran, either individually or in combinations of two or more, to maintain an aggregation-free ink state.

6. A method for manufacturing environmentally friendly solvent-based ink using III-V group colloidal quantum dots incorporating heterogeneous ligands, comprising:
(A) Preparing a quantum dot solution;
(B) Preparing a precursor solution by dispersing aromatic ligands and thiol ligands in a solvent;
(C) Stirring and mixing the precursor solution from step (B) with the quantum dot solution from step (A) to induce a reaction;
(D) Adding hexane to the reaction mixture from step (C), followed by centrifugation to precipitate the quantum dots and remove unreacted ligands;
(E) Redispersing the processed quantum dots from step (D) in a low-polarity or environmentally friendly solvent;
(F) Drying the redispersed quantum dots from step (E) to remove residual solvent; and
(G) Dispersing the dried quantum dots from step (F) in a low-polarity or environmentally friendly solvent.
Steps (D) and (E) are sequentially repeated two to three times.

7. The method of claim 6, wherein:
In step (A), the quantum dot solution is prepared with ligand-exchanged quantum dots dissolved in a solvent;
The quantum dot comprises a first compound containing indium (In) and at least one of phosphorus (P), arsenic (As), or antimony (Sb), or a second compound containing lead (Pb) and at least one of sulfur (S) or selenium (Se), selected from the group consisting of the first and second compounds;
The solvent is selected from n-octane, n-hexane, or toluene, either individually or in combinations of two or more; and
The ligand is selected from oleic acid, myristic acid, lauric acid, palmitic acid, stearic acid, oleylamine, n-octylamine, hexadecylamine, hexyl phosphonic acid, n-octyl phosphonic acid, tetradecyl phosphonic acid, or octadecyl phosphonic acid, either individually or in combinations of two or more.

8. The method of claim 6, wherein
In step (B), the solvent used for dispersing the aromatic ligand and thiol ligand is selected from chlorobenzene, 1,2-dichlorobenzene, tetrahydrofuran (THF), 2-methylanisole, 2-methyltetrahydrofuran, or toluene, either individually or in combinations of two or more; and
In step (C), the reaction is performed under a nitrogen atmosphere.

9. The method of claim 6, wherein the low-polarity or environmentally friendly solvent used in step (E) or step (G) is selected from chlorobenzene, 1,2-dichlorobenzene, tetrahydrofuran (THF), 2-methylanisole, or 2-methyltetrahydrofuran, either individually or in combinations of two or more.

10. An optoelectronic device based on optical sensing, comprising a quantum dot light absorption layer, wherein the quantum dot light absorption layer is formed by thin-film coating with quantum dot ink, which is prepared by dispersing III-V group colloidal quantum dots incorporating heterogeneous ligands in a low-polarity or environmentally friendly solvent; and
the heterogeneous ligands of the III-V group colloidal quantum dots comprise aromatic ligands and thiol ligands.

11. The optoelectronic device of claim 10, wherein the quantum dot light absorption layer has a thickness in the range of 100 nm to 1000 nm.

12. The optoelectronic device of claim 10, wherein the III-V group colloidal quantum dots are composed of chalcogenide-based quantum dots or binary compounds.

13. The optoelectronic device of claim 10, wherein the III-V group colloidal quantum dots comprise: a first compound containing indium (In) and at least one of phosphorus (P), arsenic (As), or antimony (Sb); or a second compound containing lead (Pb) and at least one of sulfur (S) or selenium (Se), wherein the quantum dots are selected from the group consisting of the first compound and the second compound.

14. The optoelectronic device of claim 10, wherein the low-polarity or environmentally friendly solvent is selected from chlorobenzene, 1,2-dichlorobenzene, tetrahydrofuran (THF), 2-methylanisole, or 2-methyltetrahydrofuran, either individually or in combinations of two or more.

15. The optoelectronic device of claim 10, wherein the quantum dot light absorption layer is formed between the electron transport layer and the hole transport layer.

16. The optoelectronic device of claim 15, wherein the electron transport layer is formed by thin-film coating and thermal treatment of a metal oxide paste selected from titanium dioxide (TiO₂), tin oxide (SnO₂), or zinc oxide (ZnO), with a thickness of 10 nm to 200 nm.

17. The optoelectronic device of claim 15, wherein the hole transport layer is composed of a metal oxide selected from nickel oxide (NiO), copper oxide (CuOx), or molybdenum oxide (MoOx), and is formed by thermal evaporation or thin-film coating, with a thickness of 5 nm to 50 nm.

18. The optoelectronic device of claim 15, wherein a transparent electrode layer is formed on the upper surface of a rigid or flexible substrate; the electron transport layer is formed on the upper surface of the transparent electrode layer; the hole transport layer is formed on the upper surface of the quantum dot light absorption layer; the electrode layer is formed on the upper surface of the hole transport layer; and the transparent electrode layer is composed of indium-tin oxide (ITO) or fluorine-doped tin oxide (FTO), with a thickness of 10 nm to 100 nm.
